(19) United States
(12) Patent Application Publication
(10) Pub. No.: US 2026/0255641 A1
(43) Pub. Date: Aug. 27, 2026

(54) POROUS PSEUDO-SUBSTRATES FOR GROUP III-NITRIDES

(71) Applicant: Wisconsin Alumni Research Foundation, Madison, WI (US)

(72) Inventors: Shubhra S. Pasayat, Middleton, WI (US); Chirag Gupta, Middleton, WI (US); Qinchen Lin, Madison, WI (US)

(21) Appl. No.: 19/065,182

(22) Filed: Feb. 27, 2025

(51) Int. Cl. H10D 62/53; H01L 21/02; H01L 21/3063; H10D 62/824

(52) U.S. Cl. CPC H10D 62/53; H10D 62/824; H10P 14/3416; H10P 50/617

(57) ABSTRACT

Methods for fabricating group III-nitride-based pseudo-substrates are provided. Also provided are pseudo-substrates made using the methods and electronic devices incorporating the pseudo-substrates. The methods combine vertical and lateral electrochemical porosification to create a porous, compliant group III-nitride layer over which a relaxed group III-nitride layer can be regrown. The porosification of the group III-nitride increases its in-plane lattice constant enabling the epitaxial regrowth of a group III-nitride having an enhanced alloy composition. The methods preserve the surface quality of the pseudo-substrate and produce a uniform porosity across the porosified layer.

### BACKGROUND

Group III-nitride semiconductors are characterized by the ability to cover a wide emission wavelength range from the deep ultraviolet (UV) to the near infrared (NIR). InGaN and AlGaN alloys can cover this emission wavelength range by tuning the indium (In) and aluminum (Al) contents in the alloy composition. For example, the large bandgap energy tunability of (Al, Ga)N from 3.4 eV for GaN to 6.1 eV for AlN allows for light emitting diodes (LEDs) spanning the ultra-violet (UV) wavelength range of 210 to 341 nm, making these alloys useful in applications such as sensing, water purification, sterilization, medical diagnostics, lithography, UV curing, security systems, and plant lighting.

Many of these applications require InGaN alloys with a suitably high indium content or AlGaN alloys with a suitably high aluminum content, and for such alloys there is a lack of high-quality and commercially available growth substrates. InGaN and AlGaN alloys have been grown on GaN substrates, but the strain induced by the lattice mismatch between the InGaN and AlGaN and the GaN substrate leads to the growth of alloys with relatively high dislocation densities, cracks, and v-pits. This limits the amount of indium or aluminum that can be incorporated into the growing alloy without sacrificing crystal quality.

One approach to reducing the lattice mismatch between a GaN growth substrate and the group III-nitrides grown thereon is the porosification of the gallium nitride via electrochemical etching. The resulting porosified layer acts as a compliance layer, enabling the regrowth of a relaxed group III-nitride overlayer having an expanded lattice constant that is closer to that of a target group III-nitride. (Shubhra Pasayat et al, Appl. Phys. Lett. 117, 062102(2020); and Pasayat, Shubhra S. et al., Materials 13, no. 1 (January 2020): 213.)

Porosification via electrochemical etching is conventionally carried out either by vertical etching or lateral etching. Vertical etching of a doped group III-nitride takes place through vertical dislocation channels in an overlying unintentionally doped material. The etching proceeds vertically from the top surface of the doped, electrically conductive group III-nitride downward into the material. However, vertical etching roughens the surface of the unintentionally doped layer because dislocation core domains-fern-like structures branching out radially from dislocation cores in the surface-are formed. Lateral etching, on the other hand, takes place through side-walls (edges) exposed in a doped electrically conductive group III-nitride. These edges are exposed by forming a dielectric cap over an unintentionally doped layer overlying the electrically conductive group III-nitride and forming trenches extending into the conductive group III-nitride. Unfortunately, the lateral etching approach leads to pore non-uniformity near the edges and is difficult to scale up to large areas. (Shubhra Pasayat et al, Materials 2020, 13, 213.)

### SUMMARY

Group III-nitride-based heterostructures for use as pseudo-substrates are provided. Also provided are methods of making the heterostructures.

One example of a heterostructure includes: a base substrate; and a pseudo-substrate stack on the base substrate. The pseudo-substrate stack comprises a single bilayer or a stack of two or more bilayers. Each bilayer includes: a compliant layer comprising a porosified n-type group III-nitride; and a layer of unintentionally doped group III-nitride on the compliant layer, wherein the layer of unintentionally doped group III-nitride has a surface comprising one or more areas comprising etched vertical threading dislocation channels separated by one or more areas that are free of etched vertical threading dislocation channels. The porosification of the one or more porosified n-type group III-nitride layers extends continuously under the one or more areas comprising etched vertical threading dislocation channels and the one or more areas that are free of etched vertical threading dislocation channels.

One example of a method of making a heterostructure includes the step of forming a pseudo-substrate stack on a base substrate, the pseudo-substrate stack comprising a single bilayer or a stack of two or more bilayers, each bilayer comprising: a layer of n-type group III-nitride; and a layer of unintentionally doped group III-nitride on the layer of n-type group III-nitride. The method further includes the steps of: forming a dielectric mask on a surface of an uppermost layer of unintentionally doped group III-nitride in the pseudo-substrate stack, wherein one or more areas of the surface of the uppermost layer of unintentionally doped group III-nitride are exposed through the dielectric mask and one or more areas of the surface of the uppermost layer of unintentionally doped group III-nitride are covered by the dielectric mask; carrying out vertical and lateral electrochemical porosification of the one or more layers of n-type group III-nitride in the pseudo-substrate stack in the presence of the dielectric mask to form one or more compliant layers of porosified n-type group III-nitride in the pseudo-substrate stack; and removing the dielectric mask from the surface of the uppermost layer of unintentionally doped group III-nitride.

### BRIEF DESCRIPTION OF THE DRAWINGS

FIG. 1 (panels (a)-(d)) is a schematic diagram showing a method of making a compliant pseudo-substrate using a dielectric electrochemical etch mask and simultaneous vertical and lateral etching.

FIGS. 2A and 2B are schematic diagrams showing a cross-sectional side view (FIG. 2A) and a top view (FIG. 2B) of a pseudo-substrate having a plurality of devices formed thereon.

FIG. 3. Scanning electron microscope (SEM) image for a 10 μm×10 μm mask pattern showing uniform pores formed continuously beneath masked and unmasked regions of an unintentionally doped group III-nitride layer, in accordance with the Example.

FIG. 4. SEM image for a 40 μm×40 μm mask pattern showing uniform pores formed continuously beneath masked and unmasked regions of an unintentionally doped group III-nitride layer, in accordance with the Example.

FIG. 5. Image showing that a dielectric layer protected the surface of an underlying unintentionally doped group III-nitride layer during electrochemical etching, as described in the Example.

FIG. 6. Image showing that a dielectric layer protected the surface of an underlying unintentionally doped group III-nitride layer during electrochemical etching for a mask pattern with square dimensions of 100 μm×100 μm and 2 μm spacing, as described in the Example.

FIG. 7. Schematic diagram of a heterostructure used in the Example.

### DETAILED DESCRIPTION

Methods for fabricating group III-nitride-based pseudo-substrates are provided. Also provided are pseudo-substrates made using the methods and electronic devices incorporating the pseudo-substrates. The methods combine vertical and lateral electrochemical porosification to create a porous, compliant group III-nitride layer, or a vertical stack of porous, compliant group III-nitride layers, over which a relaxed group III-nitride layer can be regrown. The porosification of the group III-nitride increases its in-plane lattice constant enabling the epitaxial regrowth of a group III-nitride having an enhanced alloy composition. Moreover, the methods preserve the surface quality of the pseudo-substrate and produce a uniform porosity across the porosified layer.

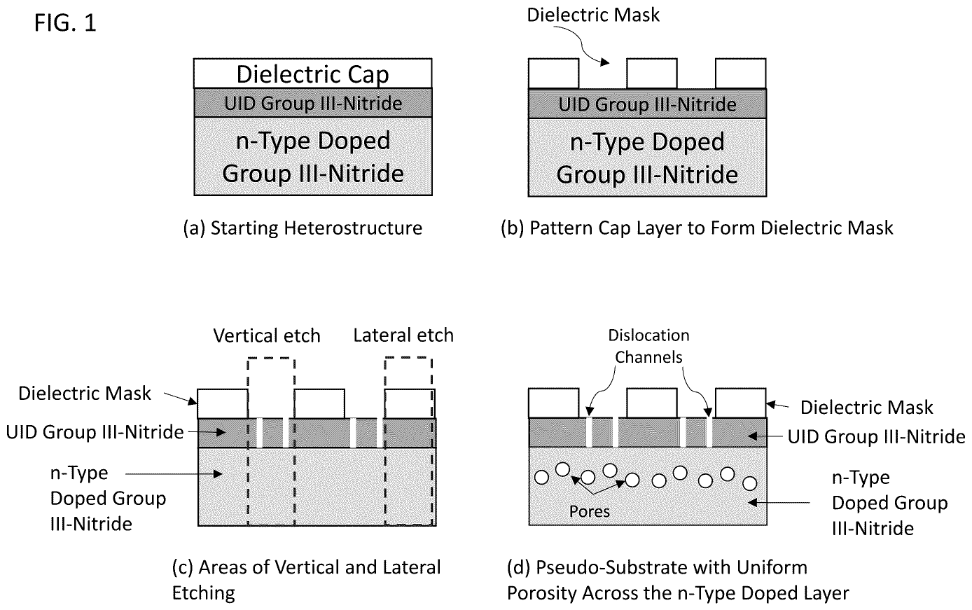

FIG. 1 (panels (a)-(d)) is a schematic diagram illustrating a method for the fabrication of a group III-nitride pseudo-substrate. The process is carried out on a heterostructure that includes a pseudo-substrate stack on a base substrate. The pseudo-substrate stack is composed of one bilayer or multiple vertically stacked bilayers and each bilayer includes a layer of an n-type doped group III-nitride, a layer of an unintentionally doped (UID) group III-nitride on the layer of n-type doped group III-nitride, and a dielectric cap layer covering the uppermost layer of unintentionally doped group III-nitride in the pseudo-substrate stack (FIG. 1, panel (a)). The n-type group III-nitride and the unintentionally doped group III-nitride may be, but need not be, the same group III-nitrides. In some embodiments, the n-type group III-nitride and the unintentionally doped group III-nitride are both gallium nitride (GaN).

The lowermost n-type group III-nitride layer in a pseudo-substrate stack may be grown on a base substrate suitable for the epitaxial growth of the group III-nitride with a crystal quality suitable for the intended application. The base substrate may include a buffer layer to reduce the lattice constant mismatch between the base substrate and the group III-nitride. Sapphire, GaN, and GaN-on-Sapphire are examples of suitable substrates.

The process begins with the patterning of the dielectric cap layer to form a dielectric mask that covers one or more areas of the upper surface of the unintentionally doped group III-nitride layer at the top of the pseudo-substate stack and through which one or more areas of the upper surface of the unintentionally doped group III-nitride are exposed (FIG. 1, panel (b)). An electrochemical etch is then carried out on the heterostructure, whereby vertical etching of the one or more n-type doped group III-nitride layers in the pseudo-substrate stack takes place through threading dislocation channels in the one or more layers of unintentionally doped group III-nitride. This vertical etching is limited to those areas of the n-type doped group III-nitride layers that underlie areas of the upper surface of the pseudo-substrate stack that are exposed through the mask. In contrast, lateral etching of the n-type doped group III-nitride layers takes place even in those areas of the n-type doped group III-nitride layers that underlie areas of the upper surface of the pseudo-substrate stack that are covered by the mask (FIG. 1, panel (c)).

The result is a compliant pseudo-substrate that includes one or more layers of n-type doped group III-nitride layer that are uniformly porosified below both the exposed and covered areas of the uppermost unintentionally doped group III-nitride layer (FIG. 1, panel (d)). Notably, the areas on the surface of the unintentionally doped group III-nitride layer that are covered by the dielectric mask are not subjected to vertical electrochemical etching of their threading dislocation channels and, therefore, remain free of the dislocation core domains that are characteristic of vertical electrochemical etching processes. As a result, upon the removal of the dielectric mask material, these surface areas lack the etched vertical threading dislocation channels that are characteristic of the surface areas that were exposed through the dielectric mask. The etching of the vertical threading dislocation channels often increases the roughness of the surface area. If this is the case, the covered surface areas that do not undergo etching of their vertical threading dislocation channels are referred to as low roughness surface areas and have a low roughness relative to the exposed areas through which vertical etching takes place. The exposed, etched surface areas are referred to as higher roughness surface areas. However, because vertical and lateral etching are carried out together, the pores in the porosified layer have uniform sizes, shapes, and distribution across the porosified layer and are not plagued by the near-edge pore non-uniformity that is characteristic of lateral electrochemical etching processes. (It should be noted that the phrases “low roughness surface areas” and “higher roughness surface areas” are not used quantitatively in this disclosure; rather, they are intended only to indicate that a low roughness surface area is distinguishable from and has a measurably lower rms surface roughness than a higher roughness surface area.)

The electrochemical etching is carried out in an electrochemical cell in which an electric potential is applied to the material to be porosified. This can be carried out by immersing the heterostructure in an electrolyte solution and connecting the electrically conductive n-type doped group III-nitride layer to a first electrode (anode). A potential is then applied between the anode and a counter electrode (cathode). If a pseudo-substrate stack includes two or more bilayers, the electrochemical etching is carried out on all of the bilayers. By way of illustration, a pseudo-substrate stack may include at least 3 bilayers, at least 5 bilayers, or at least 10 bilayers. For example, pseudo-substrate stacks having from 2 to 50 bilayers can be used.

During the electrochemical etch, holes are injected into the conductive, n-type doped group III-nitride under the influence of the electric field created by the applied potential, resulting the oxidation of the group III-nitride into a soluble form, the release of nitrogen gas, and the formation of pores. Pore size can be controlled by the applied potential, where a larger potential generally corresponds to larger pore sizes. Vertical etching of the electrically conductive group III-nitride takes place below the exposed areas of the uppermost layer of unintentionally doped group III-nitride because the electrolyte is able to access the electrically conductive group III-nitride layers through threading dislocation channels (sometimes referred to as nanopipes) in the overlying unintentionally doped layer. As a result of vertical electrochemical etching, the surface of the unintentionally doped group III-nitride is marred by dislocation core domains, which may increase the surface roughness. Dislocation core domains are characterized by a hollow core at a threading dislocation, with fern-like structures extending radially outward therefrom. (An illustrative image of dislocation cores can be found in FIG. 8(c) of Griffin, P. H., and R. A. Oliver. “Porous nitride semiconductors reviewed.” Journal of Physics D: Applied Physics 53.38 (2020 ): 383002.)

Lateral etching of the electrically conductive group III-nitride takes place where the dielectric mask overlies said electrically conductive group III-nitride. Lateral etching is allowed to continue until the sub-surface porosity extends continuously across the layer of n-type doped group III-nitride underlying both the covered and exposed portions of the uppermost unintentionally doped layer in a pseudo-substrate stack. The surface of an unintentionally doped group III-nitride layer is typically considerably smoother in those areas that are protected by the dielectric mask during the electrochemical etch due to the absence of dislocation core domains. For example, the low roughness surface areas may have an average root mean square (rms) surface roughness that is at least 20%, at least 30%, at least 40%, or at least 50% lower than the rms surface roughness of neighboring or surrounding higher roughness surface areas where vertical electrochemical etching occurs. Root mean square surface roughness measurements can be obtained via Atomic Force Microscopy (AFM) over a surface area of 5 μm² or greater, as illustrated in the Example. In absolute terms, low roughness surface areas having an rms surface roughness of, for example, less than 10 nm, less than 5 nm, and less than 4 nm (for example, rms in the range from 1 nm to 5 nm) can be achieved.

Once the porosification of the n-type doped group III nitride in the pseudo-substrate stack is complete, the dielectric mask can be removed without damaging the underlying surface of the unintentionally doped group III-nitride layer. A partially or fully strain-relaxed overlayer of another group III-nitride then can be regrown on the uppermost unintentionally doped layer and this regrown overlayer can be used as a buffer layer for the subsequent epitaxial growth of additional high-quality layers of various group III-nitrides in the subsequent fabrication of a variety of electronic devices, such as transistors, light-emitting diodes, and laser diodes.

Because the porosified layers of the pseudo-substrate have reduced mechanical stiffness, the regrown group III-nitride can be grown in a partially-or fully strain-relaxed state with a larger lattice. As a result, the group III-nitride can be regrown with a higher metal element (e.g., Al and/or In) content than would be possible without the compliant layer.

The thicknesses of the various layers making up the pseudo-substrates are not particularly limited, but should be selected to provide a crystalline material having the quality necessary for an intended application. Moreover, the regrown group III-nitride layer should be sufficiently thin that it remains strained to the lattice constant of the underlying compliant porosified group III-nitride. Illustrative layer thicknesses for the n-type doped group III-nitride include those in the range from 100 nm to 1 μm; illustrative layer thicknesses for the unintentionally doped group III-nitride layer include those in the range from 20 nm to 500 nm; and illustrative thicknesses for the elastically strain relaxed group III-nitride layer include those in the range from 100 nm to 100 μm. However, layer thicknesses outside of these ranges can be used.

The relaxed regrown group III-nitride may be regrown over the surface areas of the pseudo-substrate stack that were not subjected to vertical electrochemical etching and the surface areas of the of the pseudo-substrate stack that were subjected to vertical electrochemical etching, or may be grown over only the surface areas of the pseudo-substrate stack that were not subjected to vertical electrochemical etching. However, it is advantageous to form the active components of electronic devices on the surface areas of the regrown group III-nitride that overlie the surface areas of the pseudo-substrate stack that were not subjected to vertical electrochemical etching. This is because these surface areas will have a higher quality surface, which facilitates the epitaxial growth of high-crystal-quality overlayers for the fabrication of electronic devices with improved performance. In some embodiments, the active device layers are grown exclusively over surface areas of the unintentionally doped group III-nitride layer that were not subjected to vertical electrochemical etching. Passive device components may be, but are not necessarily, formed on surface areas of the unintentionally doped group III-nitride layer that were subjected to vertical electrochemical etching. As used herein, the term active layers refers to the layers that carry out the primary function of the electronic device. For example, in a transistor, the active layers include the channel layer through which current passes and is modulated and, in a light-emitting diode or laser, the active layers include the light-emitting layers, which may include, for example, a multiple quantum well structure.

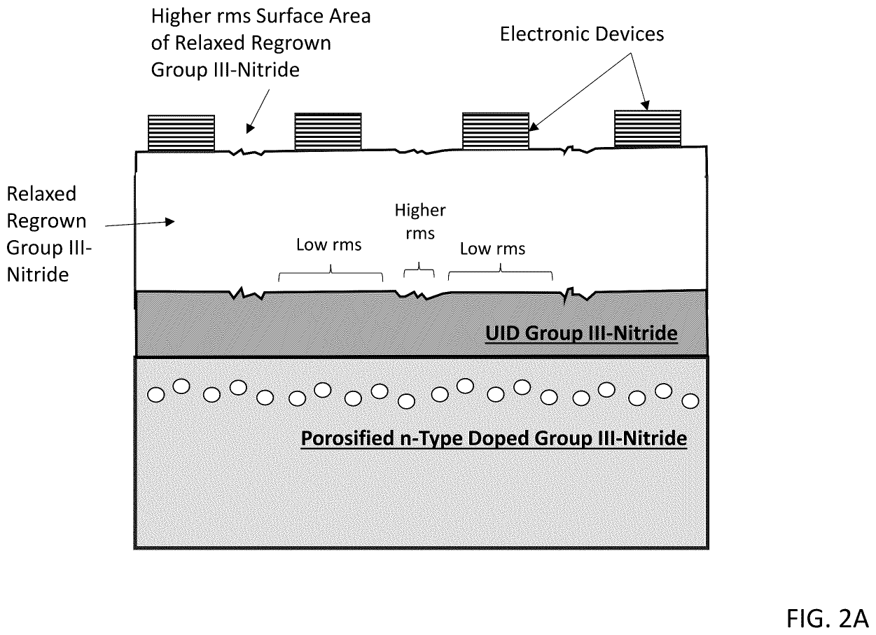

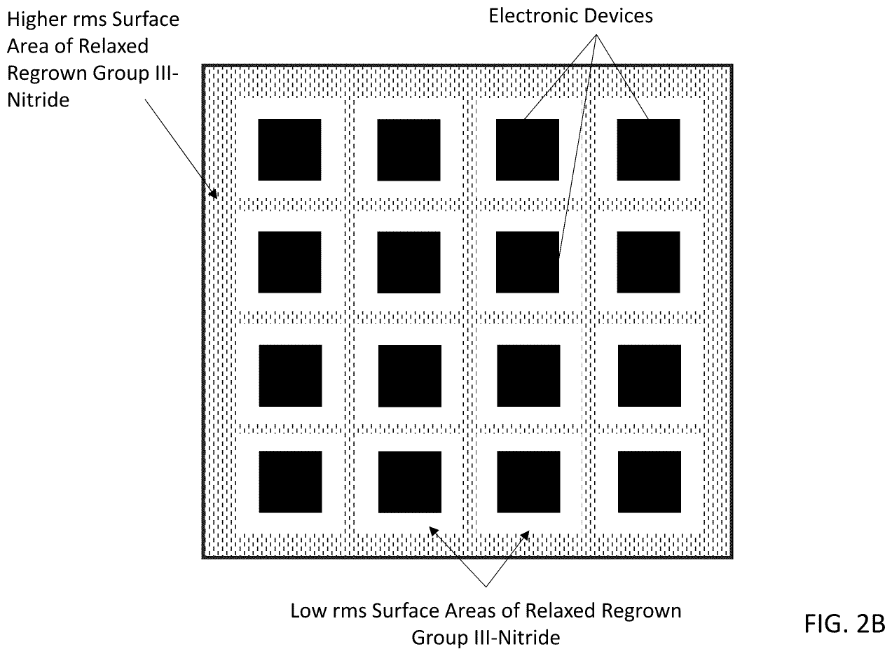

A schematic illustration of a pseudo-substrate with a plurality of devices formed thereon is provided in FIG. 2A (cross-sectional side view) and FIG. 2B (top view). For simplicity, in this example a single device is formed over each non-vertically etched surface area of the unintentionally doped group III-nitride layer (illustrated in the figure as a “low rms” roughness surface area). In the device shown here, the low roughness surface areas of the unintentionally doped group III-nitride and the corresponding low roughness surface areas of these at-least-partially relaxed group III nitrides grown thereon are arranged in a regular square pattern.

The methods described herein can be used to produce large-area pseudo-substrates, including wafer-scale pseudo-substrates. By way of illustration, pseudo-substrates having surface areas of one square centimeter (cm²), 10 cm², 100 cm², or greater can be made.

To maximize the useful non-vertically etched surface area of the pseudo-substrates, the dielectric mask can be designed so that only a small fraction of the surface area of the underlying unintentionally doped layer is exposed through the mask and affected by vertical electrochemical etching. For example, the dielectric mask may cover at least 50% of the surface area, at least 70% of the surface area, at least 90% of the surface area, or at least 95% of the surface area. The dielectric mask may, but does not necessarily, define a regular pattern on the surface of the underlying unintentionally doped layer. For example, the dielectric mask may form a square or hexagonal array pattern or a striped pattern, such that the low roughness surface areas on the unintentionally doped layer have a corresponding pattern after the electrochemical etch and removal of the mask. Arrays of low roughness surface areas may include two or more low roughness surface areas surrounded by and/or separated by the one or more higher roughness surface areas. However, a much larger number of low roughness surface areas may be created using the present methods. For example, pseudo-substrates having at least 10, at least 100, and at least 1000 discrete low roughness surface areas can be fabricated. Arrays of electronic devices may be fabricated by forming one or more electronic devices on the regrown group III-nitride over the one or more low roughness surface areas. The one or more low roughness surfaces areas may themselves have large surface areas, including, for example, surface areas of at least 5 μm², at least 10 μm², at least 100 μm², and at least 1000 μm².

Various group III-nitrides can be used in the n-type doped layer, the unintentionally doped layer, and the partially or fully elastically relaxed regrown layer. As used herein, the term “group III-nitride” is defined broadly to include group III-nitrides composed of only one or more group III elements and nitrogen, as well as transition metal nitrides alloyed with one or more group III elements. The group III-nitrides include indium-and aluminum-containing group III-nitride alloys, such as InGaN, AlGaN, and AlInGaN alloys. These alloys can be represented collectively by the general formula AlₓIn_{y}Ga_{(1-x-y)}N, where 0≤x≤1 and 0≤y≤1. Other group III-nitrides include h-BN, BGaN, BAlN, BAlGaN, AlScN, InN, ScN, AlInScN, InScN, GaScN, InGaScN, InScN, YN, AlYN, GaYN, GaInYN, AlInYN, and AlGaYN.

The n-type dopant concentration in the n-type doped layer is sufficient to render the group III-nitride electrically conductive to enable the porosification of the group III-nitride via electrochemical etching of the layer. Suitable n-type dopants include silicon, carbon, and germanium. The group III-nitride layers can be grown using known epitaxial growth techniques, such as metal-organic chemical vapor deposition (MOCVD), molecular beam epitaxy (MBE), or plasma enhanced chemical vapor deposition (PECVD).

The dielectric material used as the capping layer is non-conducting and should be impermeable to the electrolyte used during the electrochemical etch, such that electrochemical etching of the underlying n-type doped layer does not occur through the dielectric cap. Additionally, the dielectric material should be selected such that it can be selectively removed using, for example, a dry or wet chemical etch. The dielectric material may be an inorganic material, such as silicon nitride (SiNₓ), or an organic material.

### Illustrative Embodiments

One, non-limiting example of a pseudo-substrate that can be fabricated using the methods described herein includes a compliant porosified n-type doped GaN layer, an unintentionally doped GaN layer having one or more low roughness surface areas and one or more higher roughness surface areas on the n-type doped GaN layer, and a partially or fully relaxed AlGaN overlayer on the unintentionally doped GaN layer. The strain relaxation of the AlGaN alloy enables the incorporation of a higher Al content during the regrowth of the AlGaN. By way of illustration, AlₓGa₁₋ₓN alloys where x≥0.1, for example, 0.12≤x≤0.25, can be grown. The n-type GaN layer may be grown on any substrate suitable for the epitaxial growth of the GaN with a crystal quality suitable for the intended application and may include a buffer layer to reduce the lattice constant mismatch between the base substrate and the n-type doped GaN. Sapphire, GaN, and GaN-on-Sapphire are examples of suitable substrates.

Another, non-limiting example of a pseudo-substrate that can be fabricated using the methods described herein includes a compliant porosified n-type doped GaN layer, an unintentionally doped GaN layer having one or more low roughness surface areas and one or more higher roughness surface areas on the n-type doped GaN layer, and a partially or fully relaxed InGaN overlayer on the unintentionally doped GaN layer. The strain relaxation of the InGaN alloy enables the incorporation of a higher In content during the regrowth of the InGaN. By way of illustration, InₓGa₁₋ₓN alloys where x≥0.05, for example, 0.1≤x≤0.2, can be grown. The n-type GaN layer may be grown on any substrate suitable for the epitaxial growth of the GaN with a crystal quality suitable for the intended application and may include a buffer layer to reduce the lattice constant mismatch between the base substrate and the n-type doped GaN. Sapphire, GaN, and GaN-on-Sapphire are examples of suitable substrates.

### EXAMPLE

This example illustrates the fabrication of a pseudo-substrate using simultaneous vertical and lateral etching.

### Epitaxial Structure

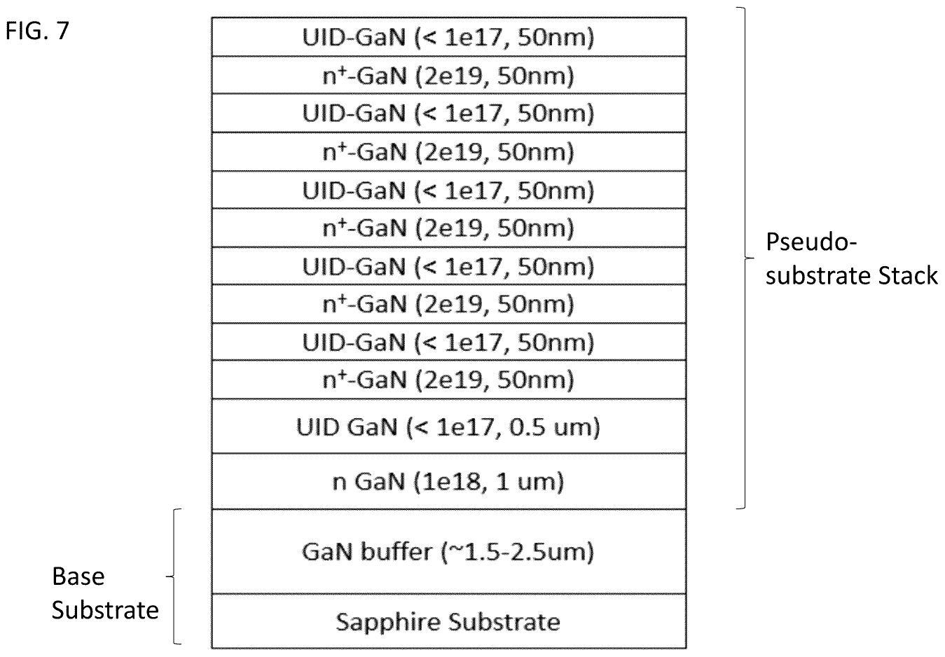

A template of GaN on sapphire was used to make a pseudo-substrate. The template consisted of a 1.5-2.5 thick μm UID GaN buffer, a 1 μm thick n-GaN buffer, a 0.5 μm thick UID GaN, and 5 pairs of n+ GaN/UID GaN superlattice layers with a thickness of 50 nm/50 nm. The dopant concentration of UID GaN, n-GaN buffer, and n+ GaN are 1e17 cm³, 1e18 cm³ and 2e19 cm³ respectively. This starting heterostructure is shown in FIG. 7.

### Fabrication Process

The fabrication process began with the deposition of a 10 nm Si₃N₄ mask layer using Plasma-Enhanced Chemical Vapor Deposition (PECVD). Standard photolithography with a photoresist mask was used to create square patterns of 10 μm×10 μm and 40 μm×40 μm, with a spacing of 2 μm between the patterns. A dry etch with fluorine-based gas was employed to selectively remove the Si₃N₄ in the unmasked regions (the 2 μm spacing), revealing underlying dislocation channels for electrochemical etching.

After dielectric patterning, the sample underwent electrochemical etching in oxalic acid to achieve porous structures. The vertical etching, shown in FIG. 1, occurred in the unmasked regions (sacrificial areas), where dislocation channels extended. The lateral etching took place beneath the masked regions, where the surface was protected by the Si₃N₄ mask. The masked regions with good surface quality can then be utilized as growth surfaces for actual devices.

### Characterization

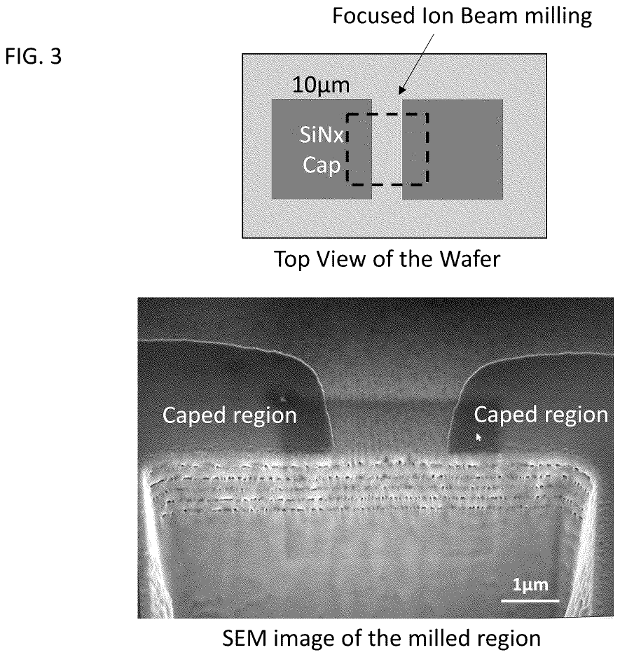

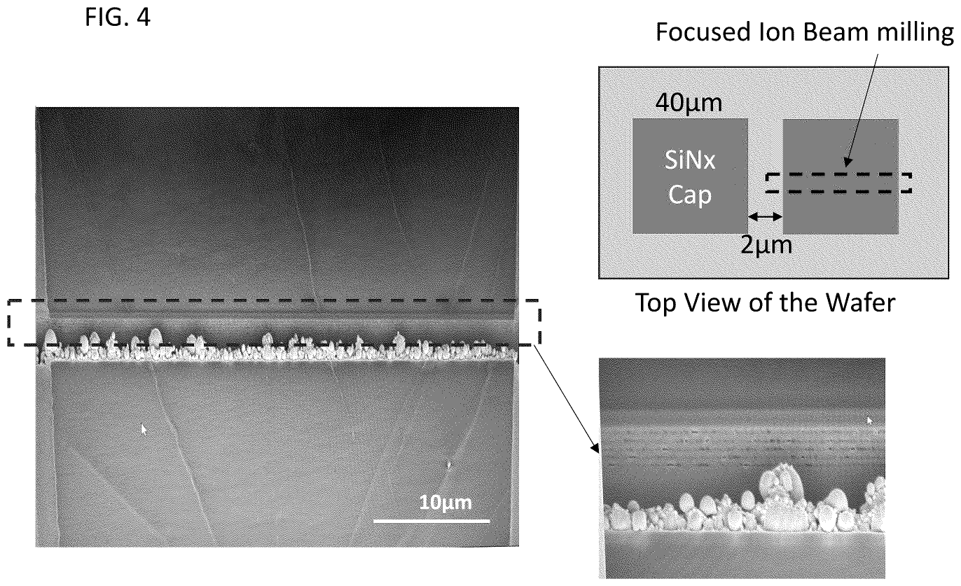

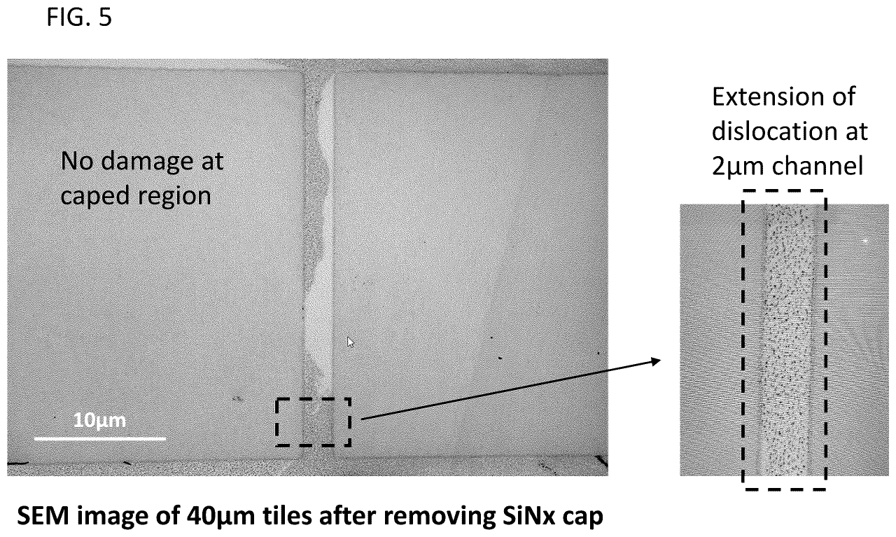

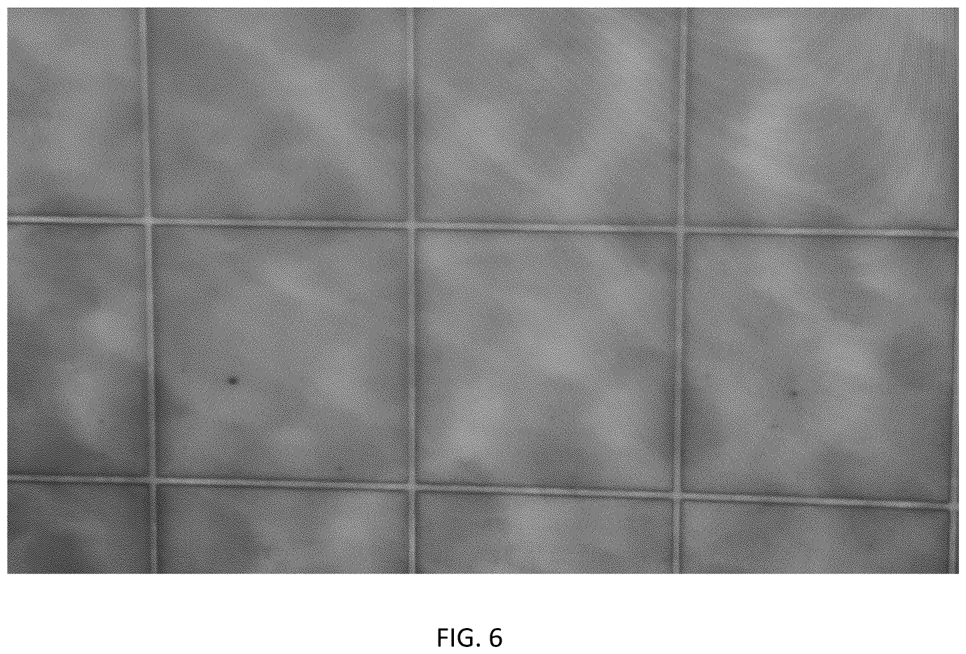

Post electrochemical etch, focused-ion-beam milling was implemented to expose the porous layers. Scanning electron microscope (SEM) images (FIG. 3 for a 10 μm×10 μm pattern and FIG. 4 for a 40 μm×40 μm pattern) showed that uniform pores were formed continuously beneath both the masked (also referred to as “capped”) and unmasked (also referred to as “uncapped”) regions. The dielectric layer protected the surface during electrochemical etching, which results in a better surface quality in the masked regions (FIG. 5). A similar approach can also be applied to larger patterns, such as the 100 μm×100 μm pattern with 2 μm spacing (FIG. 6), where a larger surface area was protected and can utilized for actual devices.

What is claimed is:

1. A heterostructure comprising:
a base substrate; and
a pseudo-substrate stack on the base substrate, the pseudo-substrate stack comprising a single bilayer or a stack of two or more bilayers, each bilayer comprising:
a compliant layer comprising a porosified n-type group III-nitride; and
a layer of unintentionally doped group III-nitride on the compliant layer, the layer of unintentionally doped group III-nitride having a surface comprising one or more areas comprising etched vertical threading dislocation channels separated by one or more areas that are free of etched vertical threading dislocation channels,
wherein the porosification of the porosified n-type group III-nitride extends continuously under the one or more areas comprising etched vertical threading dislocation channels and the one or more areas that are free of etched vertical threading dislocation channels.

2. The heterostructure of claim 1, wherein the one or more areas that are free of etched vertical threading dislocation channels have a rms roughness of 5 nm or lower and the one or more areas comprising etched vertical threading dislocation channels have a rms roughness greater than 5 nm.

3. The heterostructure of claim 1, wherein one or more areas that are free of etched vertical threading dislocation channels make up at least 90% of the total area of the surface.

4. The heterostructure of claim 1, further comprising an overlayer of an at-least-partially-elastically-relaxed group III-nitride on a top surface of the pseudo-substrate stack.

5. The heterostructure of claim 1, wherein the unintentionally doped group III-nitride and the n-type doped group III-nitride are GaN.

6. The heterostructure of claim 5, further comprising an overlayer of an at-least-partially-elastically-relaxed group III-nitride on a top surface of the pseudo-substrate stack.

7. The heterostructure of claim 6, wherein the at-least-partially-elastically-relaxed group III-nitride is an AlGaN alloy.

8. The heterostructure of claim 6, wherein the at-least-partially-elastically-relaxed group III-nitride is an InGaN alloy.

9. The heterostructure of claim 1, wherein the pseudo-substrate stack comprises at least 5 of the bilayers.

10. The heterostructure of claim 1, wherein the pseudo-substrate stack comprises 5 to 50 bilayers.

11. The heterostructure of claim 4, further comprising one or more electronic devices on the overlayer, wherein the one or more electronic devices are positioned over the one or more areas that are free of etched vertical threading dislocation channels in the unintentionally doped group III-nitride.

12. The heterostructure of claim 11, wherein the one or more electronic devices comprise transistors, light-emitting diodes, or a combination thereof.

13. A method of making a heterostructure, the method comprising:
forming a pseudo-substrate stack on a base substrate, the pseudo-substrate stack comprising a single bilayer or a stack of two or more bilayers, each bilayer comprising:
a layer of n-type group III-nitride; and
a layer of unintentionally doped group III-nitride on the layer of n-type group III-nitride;
forming a dielectric mask on a surface of an uppermost layer of unintentionally doped group III-nitride in the pseudo-substrate stack, wherein one or more areas of the surface of the uppermost layer of unintentionally doped group III-nitride are exposed through the dielectric mask and one or more areas of the surface of the uppermost layer of unintentionally doped group III-nitride are covered by the dielectric mask;
carrying out vertical and lateral electrochemical porosification of the one or more layers of n-type group III-nitride in the pseudo-substrate stack in the presence of the dielectric mask to form one or more compliant layers of porosified n-type group III-nitride in the pseudo-substrate stack; and
removing the dielectric mask from the surface of the uppermost layer of unintentionally doped group III-nitride.

14. The method of claim 13, wherein the dielectric mask covers at least 90% of the total area of the surface of the uppermost layer of unintentionally doped group III-nitride.

15. The method of claim 13, further comprising depositing an overlayer of an at-least-partially-elastically-relaxed group III-nitride on pseudo-substrate stack.

16. The method of claim 13, wherein the unintentionally doped group III-nitride and the n-type doped group III-nitride are GaN.

17. The method of claim 16, further comprising depositing an overlayer of an at-least-partially-elastically-relaxed group III-nitride on the pseudo-substrate stack.

18. The method of claim 17, wherein the at-least-partially-elastically-relaxed group III-nitride is an AlGaN alloy or an InGaN alloy.

19. The method of claim 17, further comprising forming one or more electronic devices on the overlayer, wherein the one or more electronic devices are positioned over the one or more areas of the surface of the uppermost layer of unintentionally doped group III-nitride that were covered by the dielectric mask prior to the removal of the dielectric mask.

20. The method of claim 19, wherein the one or more electronic devices comprise transistors, light-emitting diodes, or a combination thereof.
